(19) United States
(12) Patent Application Publication
(10) Pub. No.: US 2013/0106201 A1
(43) Pub. Date: May 2, 2013

(54) METHOD OF TOPOGRAPHICAL AND ELECTRICAL NANOSTRUCTURATION OF A THIN FILM OF ELECTRET POLYMER AND THIN FILM OF ELECTRET POLYMER OBTAINED

(71) Applicants: Laurence Ressier, Ramonville-Saint-Agne (FR); Etienne Palleau, Toulouse (FR)

(72) Inventors: Laurence Ressier, Ramonville-Saint-Agne (FR); Etienne Palleau, Toulouse (FR)

(73) Assignees: CENTRE NATIONAL DE LA RECHERCHE SCIENTIFIQUE (C.N.R.S.), Paris Cedex 16 (FR); INSTITUT NATIONAL DES SCIENCES APPLIQUEES DE TOULOUSE, Toulouse Cedex 4 (FR)

(21) Appl. No.: 13/696,354

(22) PCT Filed: Apr. 22, 2011
(86) PCT No.: PCT/FR2011/050934

§ 371 Date: Nov. 6, 2012

Related U.S. Application Data
(60) Provisional application No. 61/384,832, filed on Sep. 21, 2010.

(30) Foreign Application Priority Data
May 7, 2010 (FR) 10.01967

(51) Int. Cl. G11C 99/00

(52) U.S. Cl. CPC G11C 99/00
USPC 307/400; 264/293

(57) ABSTRACT

A method of nano-structuration of a thin film of electret polymer, called “electric nano-impression” method, in which a surface of a mould, called the structuration surface, including nanometric relief patterns, is placed in contact with at least one part of a free surface, called the treated surface of the thin film of electret polymer, nanometric patterns are formed, corresponding to the negative of the structuration patterns of the mould, in the thin film of electret polymer, by exerting a pressure of the structuration surface on the surface of the thin film of electret polymer, an electric voltage is applied between the structuration surface and the rear face of the film for a predetermined duration T2 suitable for inducing, after removal of the electric voltage applied, a differential distribution of electrostatic charges between the tops and the bottoms of the nanometric patterns formed in the thin electret polymer film.

The invention relates to a method for structuring a thin film of polymer electret, and to a thin film of polymer electret obtained by this method.

More particularly, the invention relates to a method for the topographical and electrical nanostructuring of a thin film of polymer electret, and to a thin film of polymer electret obtained by this method. The method according to the invention may be described as an “electrical nanoimprint” method.

Throughout the text, anything relating to the relief of a surface is referred to as “topographical”.

Throughout the text, any polymer material capable of maintaining for at least a certain duration, for example between a few hours and several months, an electrical polarisation induced by an electrical field after said electrical field has been cancelled is referred to as “polymer electret”.

Throughout the text, any recessed or relief topographical pattern whereof at least one dimension is between 1 and 1000 nm is referred to as a “nanometric pattern”.

Throughout the text, any die or tool which allows (recessed or relief) topographical patterns to be reproduced in a material is referred to as a “mould”.

Known nanolithographic techniques allow recessed patterns to be formed in a thin layer of polymer material. In particular, US 2004/0036201 describes a nanoimprint lithographic technique in which a mould having relief patterns is applied by electrostatic force to a thin layer of polymer material deposited on a substrate such that the patterns on the mould are transferred in negative to a layer of polymer material. The product obtained does not have a specific spatial distribution of electrostatic charges.

Also known is an electrical stamping (micro-contact printing) technique, which consists in bringing a stamp of soft conductive material having relief patterns into contact with a planar surface of an electret material without plastically deforming this electret material, and in applying an electrical potential difference between the stamp and the substrate on which the electret material is deposited, such that distinct zones of positive or negative charge are formed on the surface of the electret material. The product obtained does not have nanometric topographical patterns with peaks and troughs.

However, no known technique has yet been described for both topographical and electrical nanostructuring of a thin film of polymer electret.

Against all expectation, the inventors have found that it is possible to obtain a thin film of polymer electret having both recessed nanometric patterns and a specific distribution of electrostatic charges.

The invention proposes a method for structuring a thin film of polymer electret enabling said film to be structured both topographically and electrically. A method according to the invention opens up the possibility of numerous applications, for example in the field of micro- and nano-electronics, particularly for integrating nano-objects in functional devices by the electrostatic trapping of nano-objects in recessed nanometric patterns formed in a film of polymer electret.

The invention also proposes a method for structuring a thin film of polymer electret enabling said film to be structured both topographically and electrically using a single mould.

The invention proposes a method of this kind whereof implementation is simple, fast, parallel and compatible with the constraints of industrial production.

To do this, the invention relates to a method for structuring a thin film of polymer electret having a free surface, called the treated surface, and an opposing surface, called the rear face, in which:
in a first step, a surface of a mould, called the structuring surface, which includes relief nanometric patterns, called structuring patterns, and is made from a conductive or semi-conductive material, is brought into contact with at least part of the treated surface of said thin film of polymer electret,
in a second step, nanometric patterns are formed in said thin film of polymer electret, said nanometric patterns that are formed having peaks and troughs, by exerting a pressure by the structuring surface on the treated surface of said thin film of polymer electret for a duration T₁,
   characterised in that
in a third step, once said nanometric patterns have formed in the thin film of polymer electret, an electrical voltage is applied between said structuring surface of the mould and said rear face of said thin film of polymer electret for a duration T₂ which is suitable for inducing a differential distribution of electrostatic charges between the peaks and troughs of the patterns formed, and
in a fourth step, the application of electrical voltage is stopped and the mould is withdrawn from the surface of said thin film of polymer electret.

In a method according to the invention, a single mould allows a thin film of polymer electret to undergo topographical nanostructuring over surfaces of several cm², by forming nanometric topographical patterns having peaks and troughs, and electrical nanostructuring, with the nanometric patterns having a differential distribution of electrostatic charges between the peaks and troughs. Following the fourth step, once the electrical voltage applied has been cancelled, it is found that a thin film of polymer electret is obtained which has non-traversing nanometric topographical patterns having peaks and troughs and having a difference in electrostatic charge (positive or negative) between the peaks and troughs of the patterns formed. Indeed, the nanometric patterns thus formed have a difference in the electrostatic charge between the peaks and the troughs of the patterns, such that the surface potential measured at the trough of the patterns is higher (in absolute terms) than the surface potential measured at the peaks of the patterns. This phenomenon is relatively unexpected, since the electrical potential imposed on the structuring surface of the mould is the same over the entire structuring surface of the mould, so there is no inherent reason why the patterns formed in the thin film of polymer electret have a difference of this kind in the electrostatic charges. One possible explanation of this phenomenon could be that this preferential creation of charges in the trough of the patterns is due to the electrical field, which is greater locally in the troughs of the patterns formed than at the peaks thereof, the thin film of polymer electret being thinner in the troughs of the patterns formed than at the peaks.

Advantageously, the steps of the method according to the invention may be repeated in order to structure a plurality of thin films of polymer electret one after the other, re-using the same mould many times. Moreover, the use of a mould having nanometric patterns over large surfaces allows these polymer electret films to be structured on surfaces of several cm² using the same method.

Advantageously and according to the invention, the thin film of polymer electret is deposited on a substrate. The substrate may be made from any material capable of bearing the thin film of polymer electret. Advantageously and according to the invention, the substrate is made from a conductive or semi-conductive material. The substrate may for example be made from silicon.

As the material forming the thin film of polymer electret, any polymer electret which is capable of being shaped may be used. Advantageously and according to the invention, the thin film of polymer electret is made from an electret material selected from thermoplastic polymers and thermoset polymer materials.

Thus, in a first variant, advantageously and according to the invention, the material forming the thin film of polymer electret is selected from thermoplastic polymer materials. Advantageously and according to the invention, said material forming the thin film of polymer electret is selected from acrylate polymers, in particular polymethyl methacrylates (PMMA), polypropylenes (PP), polystyrenes (PS), polyvinyl chlorides (PVC), polyvinyl alcohols (PVA), polyethylene terephthalates (PET), fluoropolymers such as polytetrafluoroethylenes (PTFE) and copolymers thereof.

Advantageously and according to the invention, the thin film of polymer electret is made from a thermoplastic polymer material and, in the second step, after the film has been brought to a temperature above the glass transition temperature (Tg) of said thermoplastic polymer material, a pressure is exerted by the structuring surface of the mould on the treated surface of the thin film of polymer electret. Advantageously, all the elements are brought to a temperature above the glass transition temperature of the thermoplastic polymer material, that is to say the mould, the thin film of polymer electret and the substrate, where applicable.

In another variant embodiment according to the invention, the material forming the thin film of polymer electret is obtained from polymerisable monomers or prepolymers. These monomers or prepolymers may for example be selected from the monomers or prepolymers of thermoset polymer electrets or the monomers or prepolymers of thermoplastic polymers. In the first step, in this case, the structuring surface of the mould is brought into contact with monomers or prepolymers, which may be in liquid form. In the second step, the monomers or prepolymers are polymerised under heat or any other energy source capable of allowing this polymerisation, for example an ultraviolet (UV) source, while pressure is exerted by the structuring surface of the mould on the treated surface of the film of polymer electret.

The pressure exerted by the structuring surface on the treated surface of the thin film of polymer electret, and the duration T₁ for which the pressure is exerted, are adapted depending on the polymer material forming the film. The pressure may be applied by any means of applying pressure known to those skilled in the art and suitable for the application of pressure in a method according to the invention. Advantageously and according to the invention, the pressure exerted in the second step by the structuring surface on the treated surface of the thin film of polymer electret is between 5 N and 5 000 N, particularly between 500 N and 2 000 N. The pressure of the structuring surface of the mould on the treated surface of the thin film of polymer electret is exerted for a predetermined duration T₁ of between 1 second and 2 hours.

The thickness of the thin film of polymer electret depends on the applications envisaged. Advantageously and according to the invention, the thickness of the thin film of polymer electret is less than 5 mm, particularly less than 1 mm, in particular less than 500 nm and more particularly less than 150 nm.

The mould used in a method according to the invention may be made from any material compatible with the application of pressure which enables nanometric patterns to be formed in the thin film of polymer electret. In particular, the mould must be made from a more rigid material than the material forming the thin film of polymer electret. Moreover, advantageously and according to the invention, the mould has a structuring surface made from a conductive or semi-conductive material. In particular, advantageously and according to the invention, the mould is made from a conductive or semi-conductive material, particularly selected from silicon, n-doped silicon, for example phosphorus-doped silicon, p-doped silicon, for example boron-doped silicon, and mixtures thereof. In another variant embodiment, the mould is made from a non-conductive or slightly conductive material, and only the structuring surface of the mould is made from a conductive, semi-conductive or more conductive material than the material forming the mould. A thin metal layer may then be deposited for example on the structuring surface of the mould, by vacuum deposition or by any other known method.

The structuring patterns may have any kind of shape and size. The structuring patterns are formed by protuberances or hollows. The structuring patterns of the mould may be distributed uniformly or otherwise over the structuring surface. The height of the structuring patterns represents the largest dimension between the troughs and the peaks of each pattern. The lateral dimension of a structuring pattern corresponds to the width at the base or peak of the pattern. Advantageously and according to the invention, the structuring patterns of the mould have a smaller height than the thickness of the thin film of the polymer electret, such that the patterns formed in the thin film of polymer electret are not traversing and do not reach the rear face of the thin film of polymer electret or the surface of the substrate, where applicable. Advantageously and according to the invention, the structuring patterns of the mould have a height of between 10 nm and 990 nm, particularly 50 nm and 300 nm, and a lateral dimension of between 5 nm and 500 μm, particularly 10 nm and 50 μm, and in particular 3 μm and 10 μm.

Advantageously and according to the invention, in the third step an electrical voltage not equal to zero and of a single polarity is applied for a duration T₂ between the structuring surface and the rear face of the thin film of polymer electret. Said electrical voltage may be applied by any means suitable for creating an electrical voltage of the appropriate value between the structuring surface and the rear face of the thin film of polymer electret. To apply said electrical voltage, all that needs to be done is for example to connect an electrically conductive portion of the mould forming said structuring surface and the substrate, on which the thin film of polymer electret is deposited, to a voltage source and/or a current source. In a first variant embodiment of a method according to the invention, said electrical voltage is applied between the structuring surface and the rear face of the thin film of polymer electret by electrically connecting a first terminal of a voltage source to said structuring surface of the mould and a second terminal of said voltage source to said substrate. In this case, an electrical voltage is applied between the structuring surface and the rear face of the thin film of polymer electret, and it is possible to measure an associated electrical current and to deduce therefrom an internal resistance corresponding to the thin film of polymer electret. In a second variant, said electrical voltage is applied between the structuring surface of the mould and the rear face of the thin film of polymer electret by electrically connecting a first terminal of a current source to said structuring surface of the mould and a second terminal of said current source to said substrate. In this case, a current is in this way applied whereof the value is selected such that the desired electrical voltage is applied between the structuring surface of the mould and the rear face of the thin film of polymer electret, with the value of this current depending on the internal resistance corresponding to the thin film of polymer electret. It is also possible to combine these two variant embodiments.

The electrical voltage applied in the third step may be of direct current or in the form of pulses of the same polarity. The electrical voltage applied in the third step of a method according to the invention may be of any value not equal to zero corresponding to the voltage values that may be applied by any electrical generator, particularly adapted as a function of the material forming the thin film of polymer electret, particularly its breakdown voltage and its thickness.

Advantageously and according to the invention, in the third step, an electrical voltage not equal to zero is applied between the structuring surface of the mould and the rear face of the thin film of polymer electret, of between −200 V and +200 V, particularly between −100 V and +100 V, in particular between −50 V and +50 V, and more particularly in the order of 25 V in absolute terms. In the first variant, a voltage source which is suitable for delivering said electrical voltage is selected. In the second variant, the current source is selected such that it delivers a current suitable for forming said electrical voltage (depending on the value of the internal resistance corresponding to the thin film of polymer electret), particularly between 1 mA and 500 mA, and in particular in the order of 50 mA.

In the third step, the electrical voltage is applied for a predetermined duration which is suitable for forming a difference in the electrostatic charges between the peaks and the troughs of the patterns formed. The electrical voltage may be applied from any moment, for example in the course of the first step or in the course of the second step. To put it another way, there is no reason not to begin applying an electrical voltage between the structuring surface and the rear face of the film of polymer electret before the end of the second step and the end of the exertion of pressure by the structuring surface on the treated surface of the film of polymer electret. The electrical voltage may be applied for a total duration greater than or equal to T₂, with the total duration being greater than T₂ if the application of an electrical voltage between the structuring surface and the rear face of the film is begun before the end of the second step of a method according to the invention.

Advantageously and according to the invention, in the third step, after said nanometric patterns have been formed in the thin film of polymer electret, said electrical voltage is applied for a duration T₂ of between 1 second and 1 hour. It has been found in general that an application of voltage for a few minutes (T₂) is sufficient; for example, for a thin film of polymethyl methacrylate (PMMA) 130 nm thick, a duration of three minutes is sufficient.

Advantageously and according to the invention, after the electrical voltage applied has been cancelled, the nanometric patterns formed in the thin film of polymer electret have a difference in electrical potential not equal to zero between the peaks and troughs of the patterns of between −5 V and +5 V, particularly between −2 V and +2 V.

Advantageously and according to the invention, the thin film of polymer electret obtained following the fourth step is brought into contact with micro-objects or nano-objects. Micro-objects or nano-objects of any type and shape may be used. The micro-objects or nano-objects may be microparticles, nanoparticles, biological objects such as bacteria, viruses or proteins, or any other type of microsystem or nanosystem. These micro-objects or nano-objects may be in suspension in any kind of fluid, gas or liquid, or in the form of powders. The microparticles or nanoparticles may for example be present in the form of tubes, filaments, rods, cubes, spiny balls or spheres.

Advantageously and according to the invention, said micro-objects and/or nano-objects are electrically charged or electrically polarisable (dipoles).

Advantageously and according to the invention, the thin film of polymer electret obtained following the fourth step is immersed in a colloidal solution of nanoparticles.

The invention also relates to a thin film made of polymer electret material obtained by a method according to the invention, characterised in that it includes non-traversing nanometric patterns having peaks and troughs and having a differential distribution of electrostatic charges between the peaks and troughs of the patterns. Following a method according to the invention, the treated surface of the starting thin film is topographically and electrically structured.

After having been brought into contact with micro-objects and/or nano-objects, the thin film which is obtained by a method according to the invention has a differential distribution of the micro-objects and/or nano-objects between the peaks and troughs of the nanometric patterns formed. Advantageously and according to the invention, said thin film obtained by a method according to the invention is characterised in that micro-objects and/or nano-objects, in particular nanoparticles, are disposed selectively, substantially only in the troughs of the nanometric patterns formed.

Advantageously and according to the invention, the micro-objects and/or nano-objects are electrostatically trapped in said nanometric patterns formed.

Said micro-objects and/or nano-objects, in particular said nanoparticles, may be disposed in the troughs of the nanometric patterns formed such that they form one or more layers, continuous or otherwise.

The invention also relates to a method for nanostructuring a thin film of polymer electret, and to a thin film of polymer electret material, which are characterised in combination by all or some of the features mentioned above or below.

Other objects, advantages and features of the invention will become apparent from reading the description of examples below, which refer to the attached figures, in which:

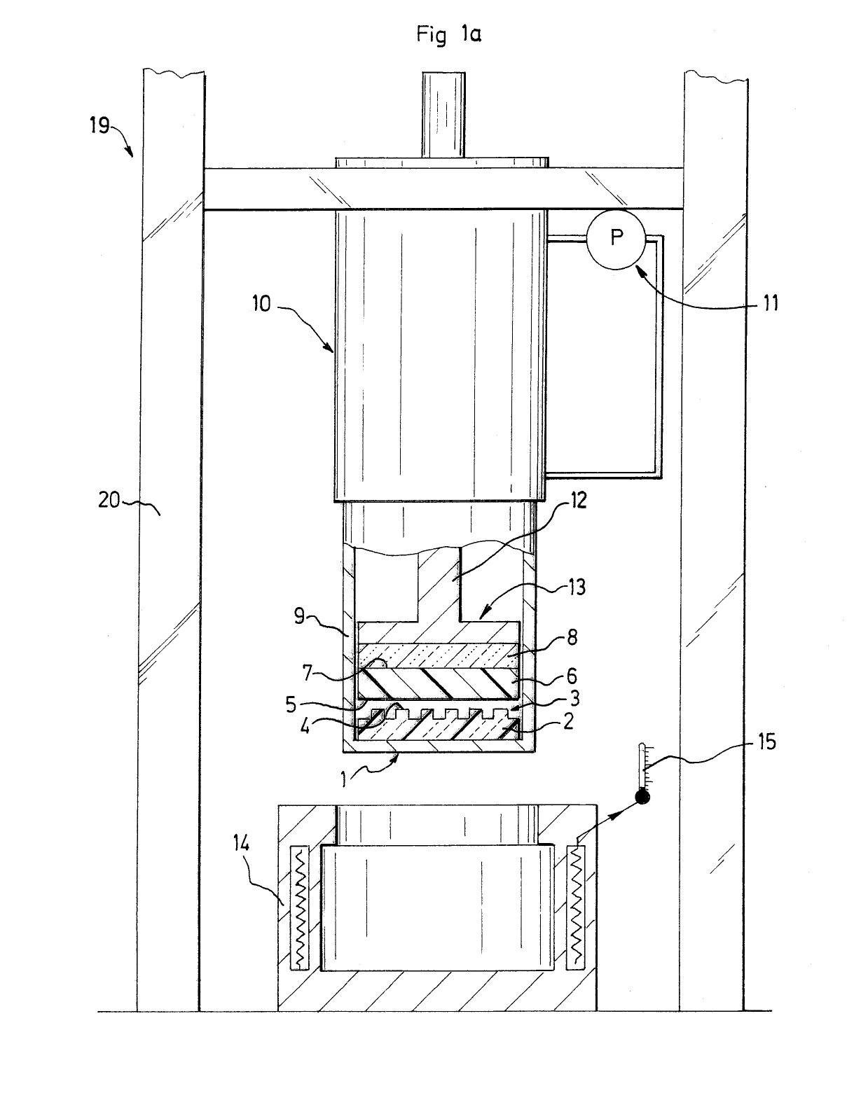

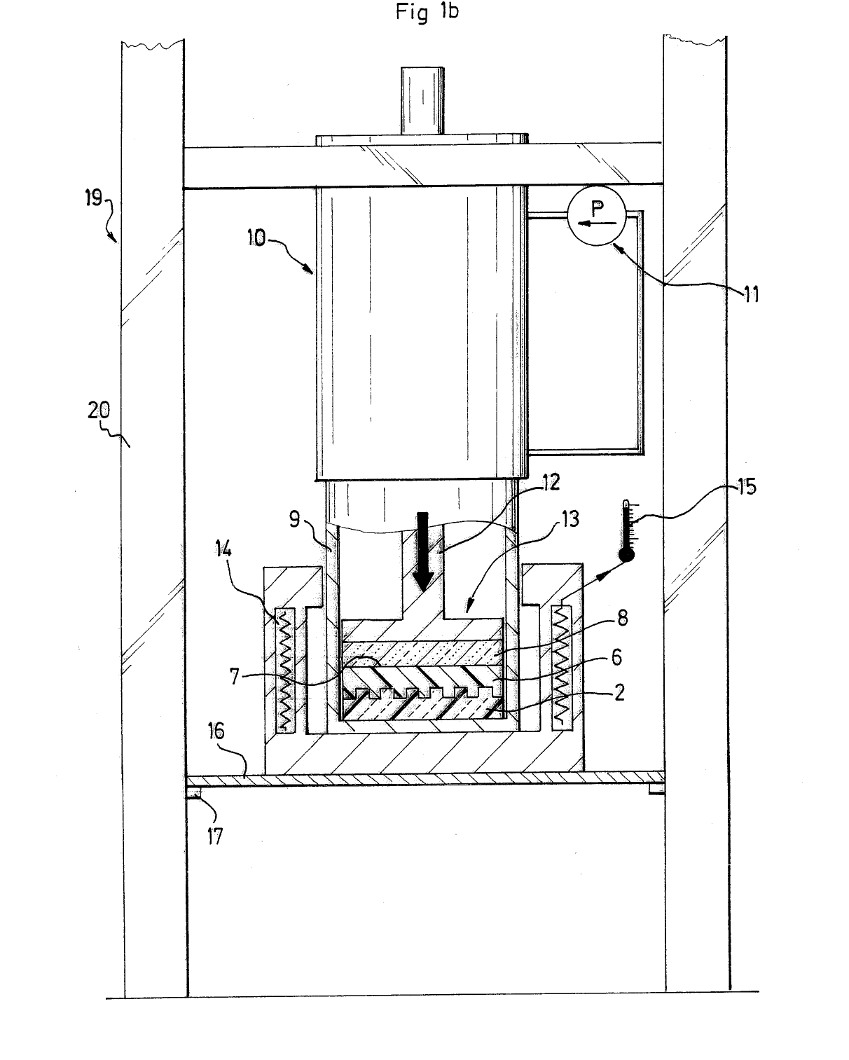

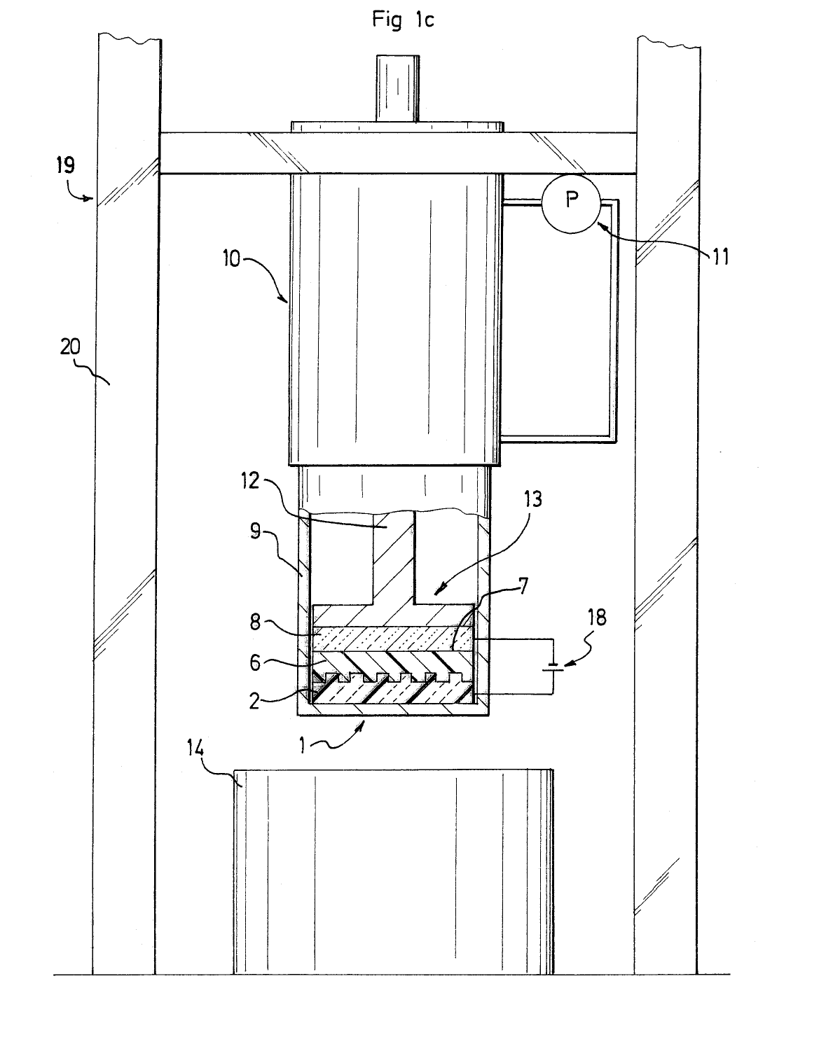

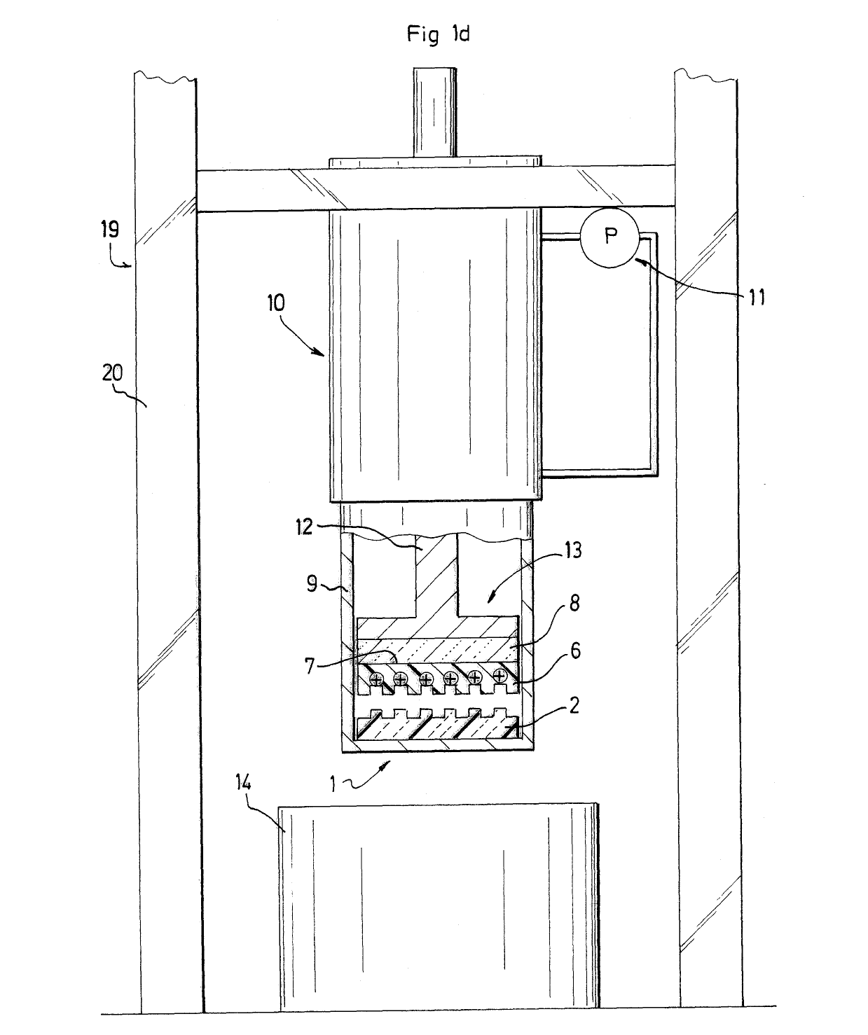

FIG. 1a is a schematic view illustrating the first step of a method according to the invention,

FIG. 1b is a schematic view illustrating the second step of a method according to the invention,

FIG. 1c is a schematic view illustrating the third step of a method according to the invention,

FIG. 1d is a schematic view illustrating the fourth step of a method according to the invention,

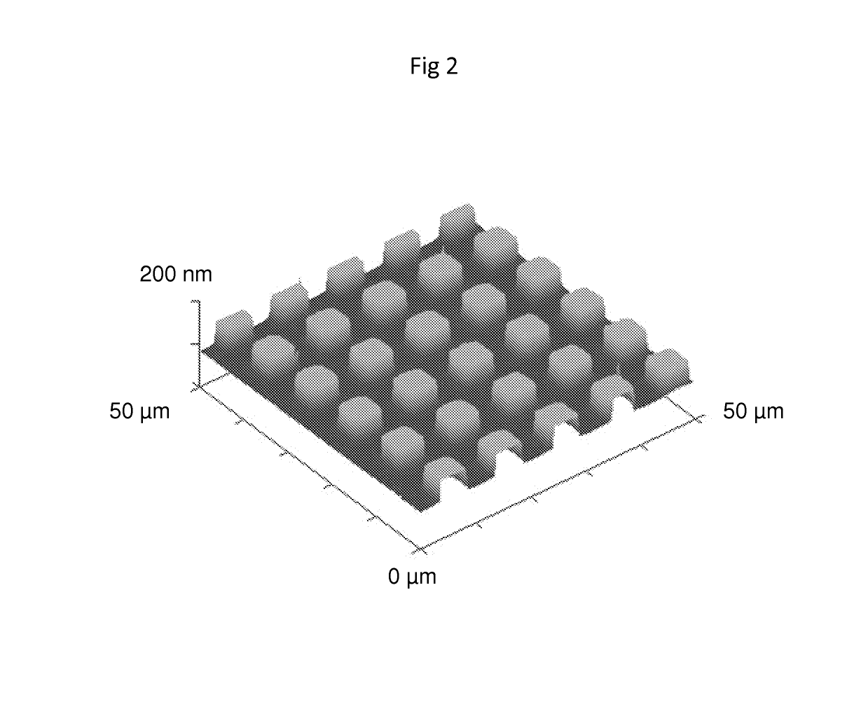

FIG. 2 is a topographical three-dimensional image, obtained by atomic force microscopy (AFM), of part of the structuring surface of a mould, bearing relief patterns, which is used in a method according to the invention,

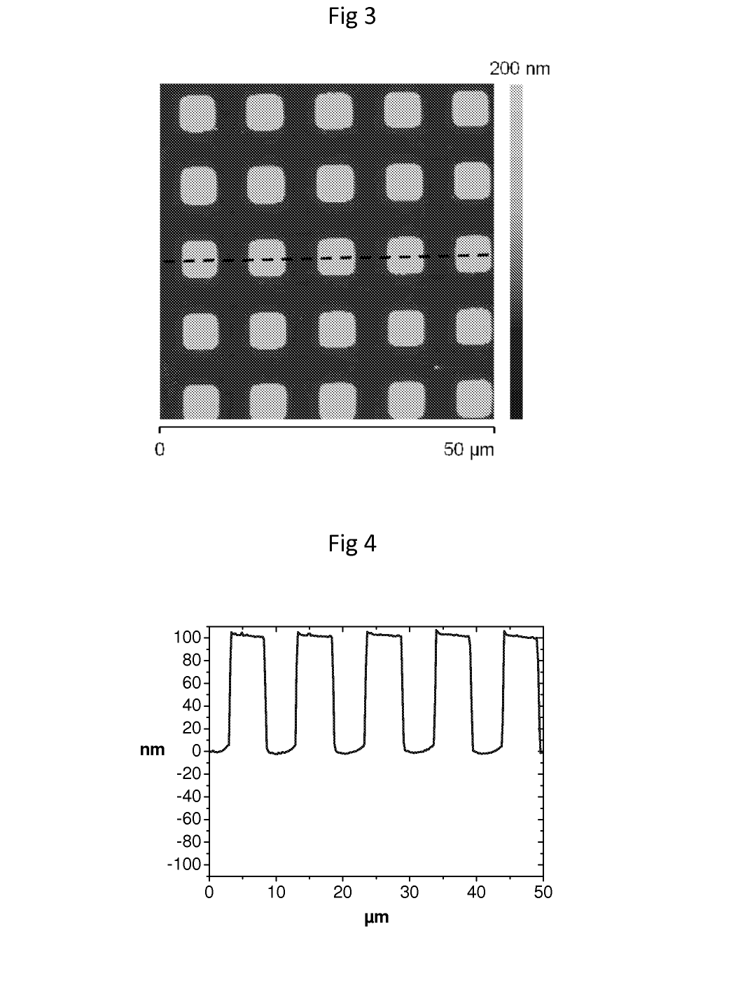

FIG. 3 is a topographical image, obtained by atomic force microscopy (AFM), of the same part as that shown in FIG. 2, of the structuring surface of a mould, bearing relief patterns, which is used in a method according to the invention,

FIG. 4 is a graph of the topographical profile of the structuring surface of a mould, along the dashed line marked on the corresponding image in FIG. 3, bearing relief patterns, which is used in a method according to the invention,

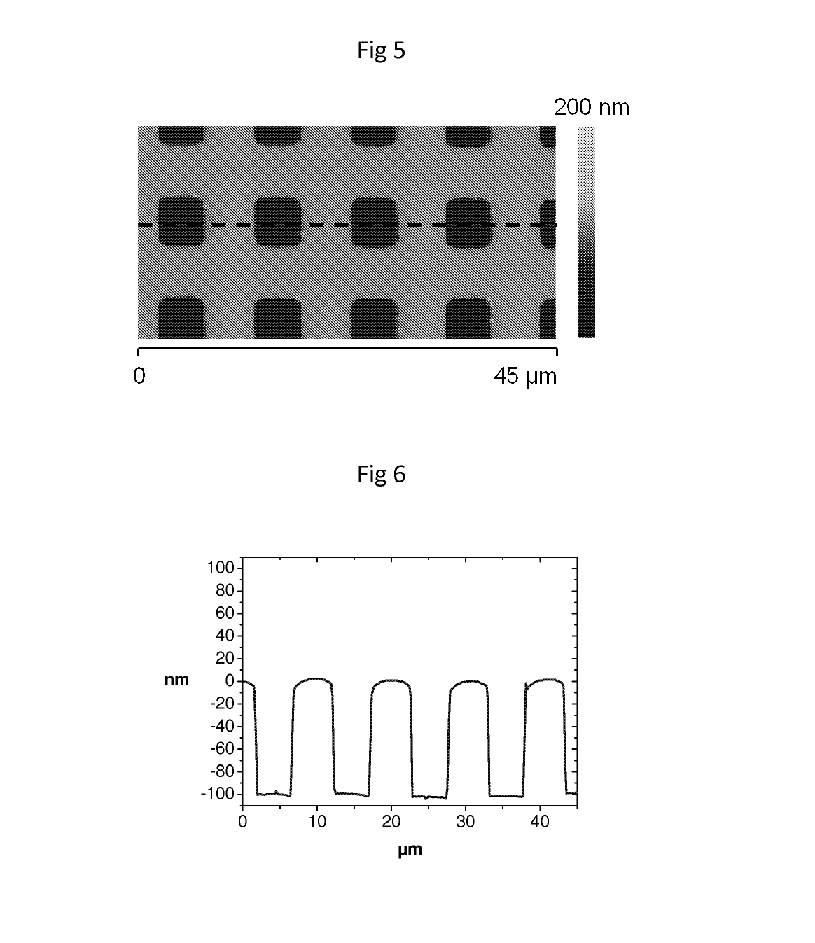

FIG. 5 is a topographical image, obtained by atomic force microscopy (AFM), of part of the structured surface of a thin film of polymer electret obtained by a method according to the invention,

FIG. 6 is a graph of the topographical profile, along the dashed line marked on the corresponding image in FIG. 5, of the structured surface of a thin film of polymer electret obtained by a method according to the invention,

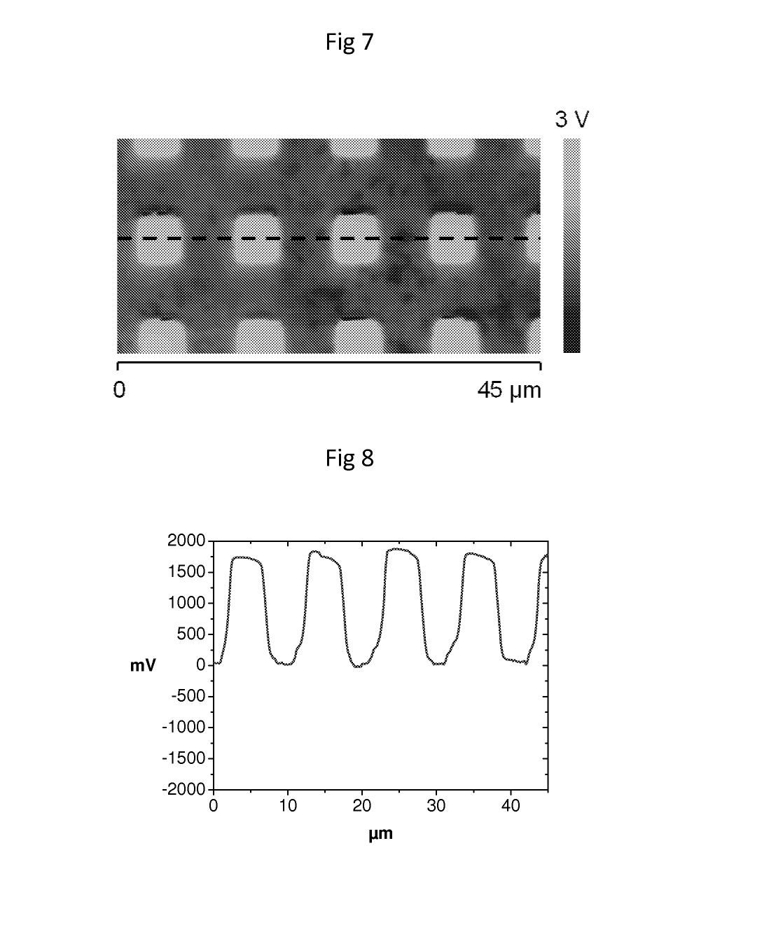

FIG. 7 is an image of the surface potential, obtained by Kelvin force microscopy (KFM), of the same part as that shown in FIG. 5, of the structured surface of a thin film of polymer electret obtained by a method according to the invention,

FIG. 8 is a graph of the surface potential profile, along the dashed line marked on the corresponding image in FIG. 7, of part of the structured surface of a thin film of polymer electret obtained by a method according to the invention,

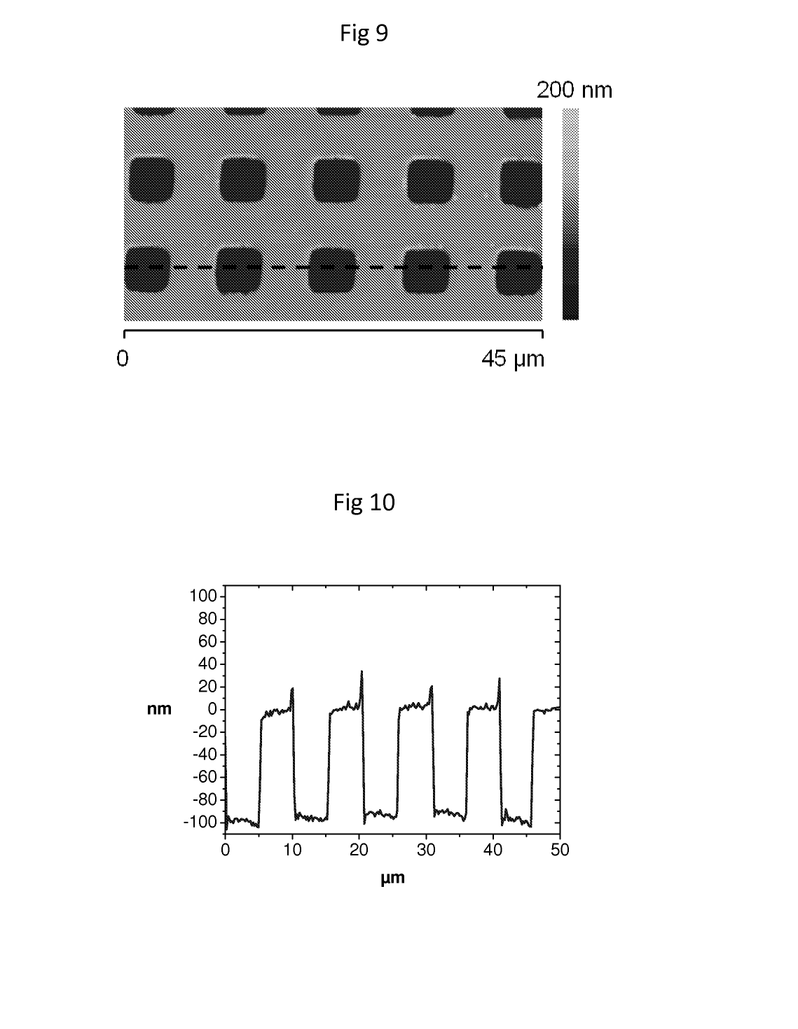

FIG. 9 is a topographical image, obtained by atomic force microscopy (AFM), of part of the structured surface of a thin film of polymer electret obtained by a method according to the invention,

FIG. 10 is a graph of the topographical profile, along the line marked in dashes on the corresponding image in FIG. 9, of the structured surface of a thin film of polymer electret obtained by a method according to the invention,

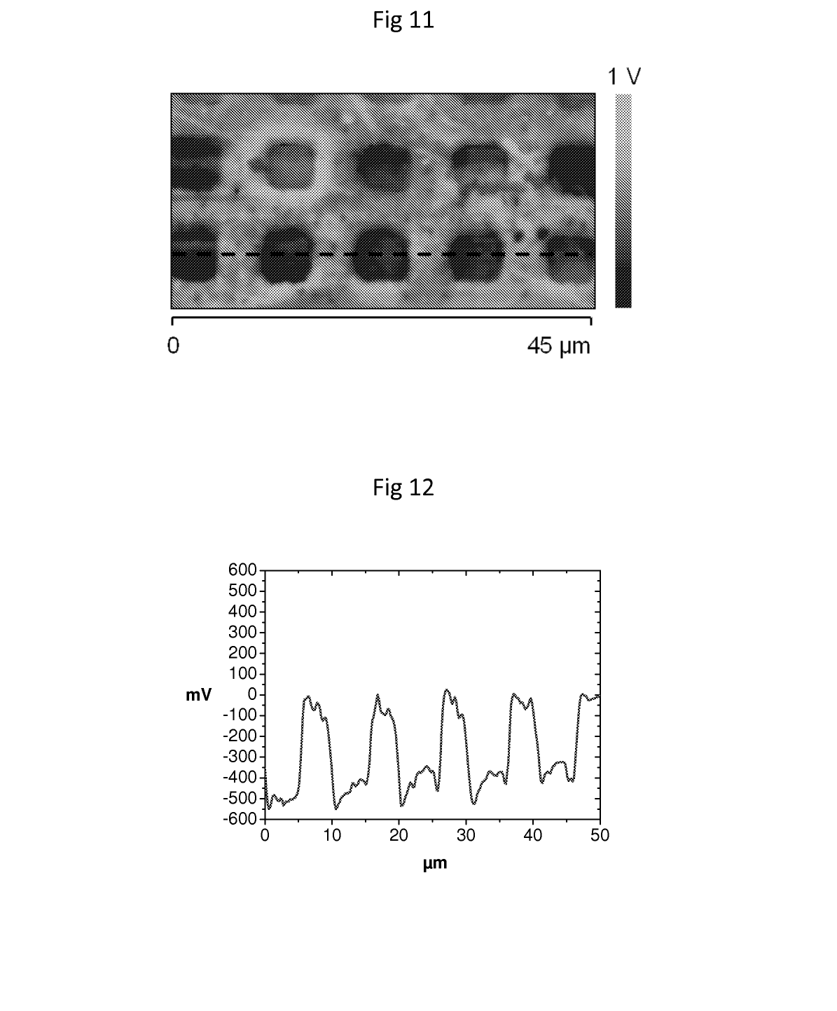

FIG. 11 is an image of the surface potential, obtained by Kelvin force microscopy (KFM), of the same part as that shown in FIG. 9, of the structured surface of a thin film of polymer electret obtained by a method according to the invention,

FIG. 12 is a graph of the surface potential profile, along the dashed line marked on the corresponding image in FIG. 11, of part of the structured surface of a thin film of polymer electret obtained by a method according to the invention,

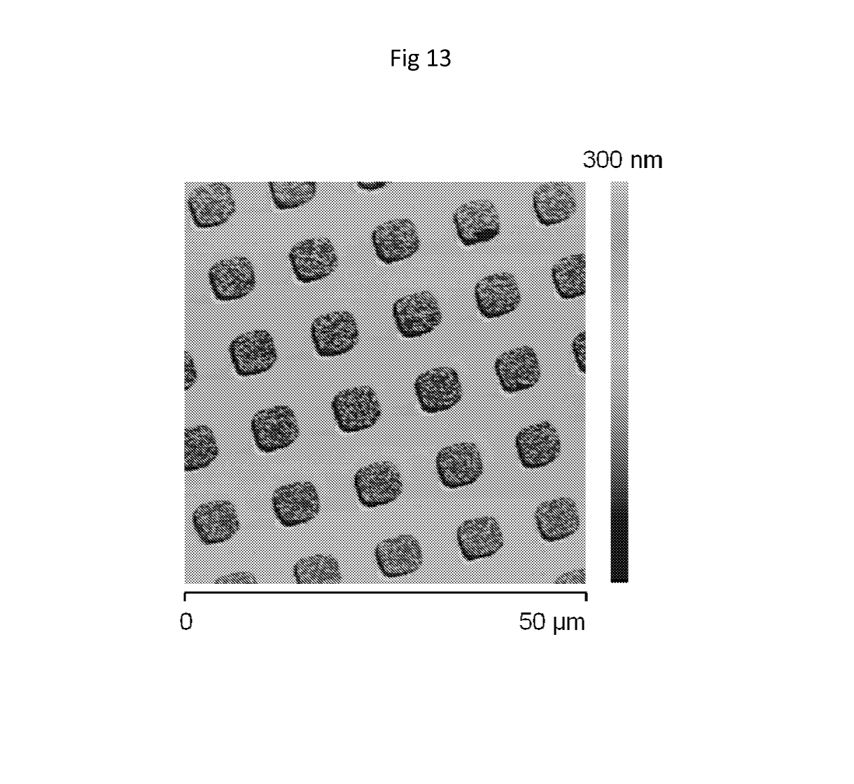

FIG. 13 is a topographical image, obtained by atomic force microscopy (AFM), of part of the structured surface of a thin film of polymer electret obtained by a method according to the invention, after it has been brought into contact with nanoparticles, and

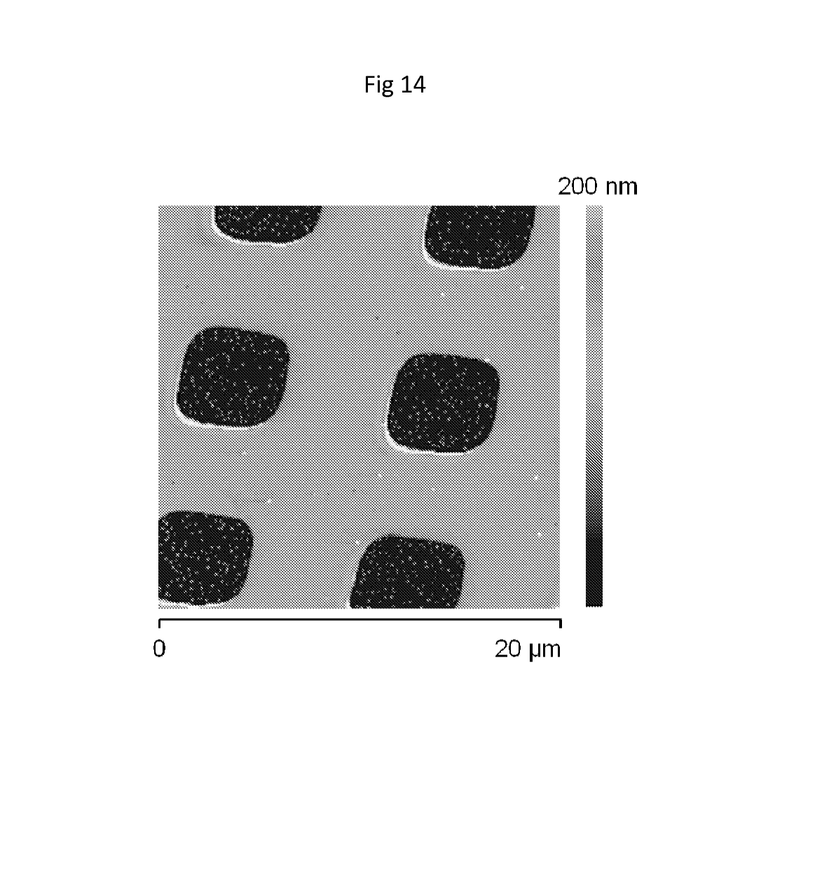

FIG. 14 is a topographical image, obtained by atomic force microscopy (AFM), of the same part as that shown in FIG. 13 of the structured surface of a thin film of polymer electret obtained by a method according to the invention, after it has been brought into contact with nanoparticles.

FIGS. 1a to 1d are not to scale, for the purpose of illustration. In FIGS. 3, 5, 9, 13 and 14, which show topographical images, the darkest zones correspond to the zones lowest down, and the palest zones correspond to the zones highest up; the topographical amplitude shown is indicated above the corresponding scale of grey values. In FIGS. 7 and 11, relating to the surface potential, the darkest zones correspond to the zones with the smallest surface potential, and the palest zones correspond to the zones having a higher surface potential; the amplitude of the surface potential shown is indicated above the corresponding scale of grey values.

A machine 19 including a frame 20 is used to implement a method according to the invention. The machine 19 comprises a fixed part 10, in which there slides a piston 12 that is made longer by a plate 13. A regulating means 11 allows the pressure P exerted by a mould 2 on the free surface, called the treated surface 5, of a thin film 6 of polymer electret to be regulated. A substrate 8, on which the film 6 of polymer electret is deposited, is fixed to the plate 13 of the piston 12, particularly by suction. The fixed part 10 is made longer by a support element 9. The plate 13 is suitable for being able to exert a pressure on the substrate 8 of the thin film 6 of polymer electret in such a way that a pressure is exerted by the mould on the treated surface 5 of the thin film 6 of polymer electret.

The mould 2 has a surface, called the structuring surface 4, including relief nanometric patterns 3, called structuring patterns, formed by protuberances. The structuring surface 4 is made from a conductive or semi-conductive material. The mould 2 may be made by a photolithography method, followed by a wet etching step. The mould 2 may be made from a conductive or semi-conductive material, particularly selected from silicon, n-doped silicon, for example phosphorus-doped silicon, p-doped silicon, for example boron-doped silicon, and mixtures thereof. In another variant embodiment, the mould 2 may be made from a transparent material, particularly a material which is transparent to ultraviolet rays, allowing an ultraviolet source to be used for polymerisation of the monomers or prepolymers intended to form the thin film 6 of polymer electret.

The mould 2 is disposed on the base 1 of the support element 9, with the structuring surface 4 of the mould 2 disposed on the piston plate 13 side. The substrate 8 is fixed on the surface of the plate 13 opposite the mould 2 such that the free surface, called the treated surface 5, of the film 6 deposited on the substrate 8 is disposed opposite the structuring surface 4 of the mould. The opposite surface of the film 6, called the rear face 7 of the film, is in contact with the substrate 8.

In a first step, shown in FIG. 1a, the structuring surface 4 is brought into contact with at least part of the planar treated surface 5 of the thin film 6 of polymer electret deposited on the substrate 8 made of conductive or semi-conductive material.

The structuring patterns of the structuring surface 4 of the mould 2 have planar surfaces. In particular, the peaks and troughs of the structuring patterns have planar surfaces, with each of the planar surfaces that form the peaks and each of the planar surfaces that form the troughs of the structuring patterns being respectively located in a single plane. Moreover, the surfaces forming the troughs of the structuring patterns are preferably parallel to the surfaces forming the peaks of the patterns. According to the invention, the structuring patterns may also take any form having troughs and peaks. On the other hand, the lateral spacing between the peaks and the troughs of the structuring patterns may be regular or otherwise. The lateral spacing between the peaks and the troughs of the structuring patterns is advantageously suitable for obtaining a difference in the electrostatic charges between the peaks and the troughs of the recessed patterns formed in the thin film of polymer electret.

The invention also applies in cases where the structuring patterns are hollows extending in recessed manner in the mould.

In a second step, shown in FIG. 1b, pressure is exerted by the structuring surface 4 on the treated surface 5 of said thin film 6 of polymer electret, in conditions suitable for allowing recessed nanometric patterns to be formed in the thin film 6 of polymer electret. The pressure exerted is regulated with the aid of the means 11 for regulating the pressure exerted by the plate 13. An enclosure 14 equipped with one or more heating means and a means 15 for regulating temperature, such as an oven 14, is disposed such that it can bring the mould 2, the substrate and the thin film 6 of thermoplastic polymer to a temperature above the glass transition temperature of said thermoplastic polymer material forming the thin film of polymer electret. Advantageously, the oven 14 is disposed on a plate 16 which is fixed to the frame 20 of the machine 19 with the aid of fixing parts 17.

The oven 14 is then withdrawn such that the substrate 8, the thin film 6 of polymer electret and the mould 2 reach a temperature below the glass transition temperature of the polymer material that forms the film 6. The nanometric patterns are formed once the temperature of the film of polymer electret is below the glass transition temperature, in the case of a thermoplastic polymer, and once the polymerisation of the monomer has taken place, in the case of a thermoset polymer. Following the second step, the nanometric patterns are thus capable of maintaining their shape once the mould is removed.

In a third step, shown in FIG. 1c, after said recessed nanometric patterns have been formed in the thin film 6 of polymer electret, a positive electrical voltage is applied, as seen in the diagram, between said structuring surface 4 and said rear face of the film 6, that is to say between the structuring surface and the substrate 8, for a predetermined duration T₂ which is suitable for inducing a difference in the electrostatic charges between the peaks and the troughs of the patterns. The mould 2 is made from a conductive or semi-conductive material which is identical to the material forming the structuring surface 4 of the mould. Electrical contacts are made in the mould 2 and the substrate 8 and connected to an electrical voltage generator 18.

The entire structuring surface of the mould is electrically polarised by an electrical voltage, with the electrical potential of the structuring surface of the mould being different from the electrical potential of the treated surface 5 of the thin film 6 of polymer electret.

In a fourth step, shown in FIG. 1d, the application of electrical voltage is stopped and the mould 2 is withdrawn from the surface of the thin film 6 of polymer electret. It is found that in this case, following the application of a positive electrical voltage, the troughs of the nanometric patterns formed in the thin film of polymer electret are positively charged to a very significant extent in relation to the peaks of the patterns.

### EXAMPLE 1

### Preparation of a Thin Film of Polymer Electret Including Non-Traversing, Positively Charged Recessed Nanometric Patterns

A mould composed of a plate of p-doped silicon (10¹⁸ atoms/cm³) which had sides 5 mm long and was 275 μm thick, including networks of patterns formed by squares which had sides 5 μm long and were 100 nm high, was formed by photolithography and wet etching. In each of the networks of patterns, the patterns were separated by a lateral spacing of 5 μm. FIG. 2 is a topographical three-dimensional perspective image, obtained by atomic force microscopy (AFM), of part of the surface of this mould, including the relief structuring patterns. FIG. 3 is a topographical image of this same mould, as seen from the side of the mould, obtained by atomic force microscopy (AFM), having relief patterns, and FIG. 4 is a graph of the topographical profile of the structuring surface of the mould along the segment shown in FIG. 3.

A solution of polymethyl methacrylate (PMMA) was prepared by diluting granules of PMMA in powder form, such as those sold by SIGMA ALDRICH (St. Louis, USA), having a molecular weight in the order of 15 000 g/mole and a glass transition temperature of 100° C., in methyl isobutyl ketone (MIBK) to a concentration in the order of 40 g/litre. The prepared solution of PMMA was deposited on a substrate of p-doped silicon (10¹⁶ atoms/cm³) which had sides 1 cm long and was 500 μm thick, by spin-coating with the aid of a spinner (acceleration of 5 000 rev/min², speed 2 000 rpm for 30 seconds). The silicon plate was then placed on a heating panel such that the MIBK solvent still present in the deposited film of PMMA evaporated. The thin film of PMMA obtained was deposited on the silicon substrate at a thickness of 130 nm.

The mould was disposed opposite the film of PMMA borne by the silicon substrate, and the system was brought to a temperature above the glass transition temperature of the PMMA, namely 130° C., in an oven. A mechanical pressure by the mould of 1 000 N was then exerted on the treated surface of the film of PMMA for 30 minutes, and then the system was cooled to a temperature of 50° C. An electrical voltage of +20 V was then applied for 3 minutes between the structuring surface of the mould and the rear face of the film, with the substrate being connected to earth. An associated current of 50 mA was measured while this voltage was being applied. The mould was then removed.

A thin film of PMMA was obtained, including non-traversing recessed nanometric patterns having a depth of 100 nm and with a difference in the electrostatic charges between the peaks and troughs of the recessed patterns formed. The topography of the structured surface of the thin film of PMMA obtained is shown in FIGS. 5 and 6, where FIG. 6 shows the topographical profile of the structured surface along the dashed line indicated on the corresponding image in FIG. 5 (with the direction of said dashed line on the x axis and the depth on the y axis). In FIG. 6, the zero on the y axis scale substantially coincides with the level of the peaks of the patterns. The recessed nanometric patterns formed in the film of PMMA correspond to the negative of the structuring patterns on the mould used. The recessed nanometric patterns formed in the film of PMMA have a surface potential in the order of +1800 mV in relation to the peaks of the patterns. The surface potential of the structured surface of the thin film of PMMA obtained is shown in FIGS. 7 and 8, where FIG. 8 shows the profile of the structured surface potential along the dashed line marked on the corresponding image in FIG. 7 (with the direction of said dashed line on the x axis and the potential on the y axis). In FIG. 8, the zero on the y axis scale substantially coincides with the level of the peaks of the patterns.

Moreover, the same measurements using Kelvin force microscopy (KFM) were carried out on this film, particularly after 24 hours and after 3 months, during which the film was kept at a temperature of 21° C. and at atmospheric pressure (1 013.25 hPa), in air at a relative humidity in the order of 40%. A decrease in the surface potential of the nanometric patterns in the order of 50% was observed after 24 hours, then the surface potential remained stable, with the surface potential measured 3 months later being substantially equal to the surface potential measured after 24 hours.

### EXAMPLE 2

### Preparation of a Thin Film of Polymer Electret Including Non-Traversing, Negatively Charged Recessed Nanometric Patterns

In the same way as in Example 1, the same mould was used and a thin film of PMMA was deposited on a silicon substrate in the same way, but an electrical voltage of −50 V was applied (instead of +20 V). An associated current of 50 mA was measured while this voltage was being applied.

On removal of the mould, a thin film of PMMA was obtained, including non-traversing recessed nanometric patterns having a depth of 100 nm and with a difference in the electrostatic charges between the peaks and troughs of the recessed patterns formed. The topography of the structured surface of the thin film of PMMA obtained is shown in FIGS. 9 and 10, where FIG. 10 shows the topographical profile of the structured surface along the dashed line marked on the corresponding image in FIG. 9 (with the direction of said dashed line on the x axis and the depth on the y axis). In FIG. 10, the zero on the y axis scale substantially coincides with the level of the peaks of the patterns. The recessed nanometric patterns formed in the film of PMMA correspond to the negative of the structuring patterns on the mould used. The recessed nanometric patterns formed in the film of PMMA have a surface potential in the order of −450 mV in relation to the peaks of the patterns. The surface potential of the structured surface of the thin film of PMMA obtained is shown in FIGS. 11 and 12, where FIG. 12 shows the profile of the structured surface potential along the dashed line marked on the corresponding image in FIG. 11 (with the direction of said dashed line on the x axis and the potential on the y axis). In FIG. 12, the zero on the y axis scale substantially coincides with the level of the peaks of the patterns.

The measurements using Kelvin force microscopy (KFM) were carried out again on the same film, particularly after 24 hours and after 3 months, during which the film was kept at a temperature of 21° C. and at atmospheric pressure (1 013.25 hPa), in air at a relative humidity in the order of 40%. A decrease in the surface potential (in absolute terms) of the nanometric patterns in the order of 50% was observed after 24 hours, then the surface potential remained stable, with the surface potential measured 3 months later being substantially equal to the surface potential measured after 24 hours.

### EXAMPLE 3

### Preparation of a Film of Polymer Electret with Nanoparticles Trapped in the Recessed Nanometric Patterns

The film prepared in Example 1 was immersed in a colloidal solution of nanoparticles of latex (18×10¹⁰ nanoparticles/ml) in isopropanol. The latex nanoparticles used, which were spherical in shape, were 100 nm across and functionalised with negatively charged carboxyl groups. After being immersed in this colloidal solution for one minute and then washed in isopropanol for 30 seconds, the film obtained was dried in a stream of nitrogen.

Observation of the surface of the film obtained, using atomic force microscopy (AFM) (FIGS. 13 and 14), showed that the nanoparticles of latex had selectively gathered within the recessed patterns formed in the thin layer of PMMA, forming a layer of latex nanoparticles in the recessed patterns. FIG. 14 corresponds to a zoom of the central part of the surface of the film shown in FIG. 13. A thin film of PMMA was thus obtained that included non-traversing recessed nanometric patterns in which the latex nanoparticles had been electrostatically trapped. The surface of the thin film of PMMA forming the top of the patterns included substantially no nanoparticles.

Moreover, the invention may form the subject of different variants and numerous other applications in respect of the embodiments and examples described above. For example, it is possible to create patterns in the form of grooves from a mould having patterns in the form of lines 200 nm wide, 100 nm high and 2 μm long.

1. Method for structuring a thin film (6) of polymer electret having a free surface, called the treated surface (5), and an opposing surface, called the rear face (7), in which:
in a first step, a surface of a mould (2), called the structuring surface (4), which includes relief nanometric patterns, called structuring patterns, and is made from a conductive or semi-conductive material, is brought into contact with at least part of the treated surface (5) of said thin film (6) of polymer electret,
in a second step, nanometric patterns are formed in said thin film (6) of polymer electret, said nanometric patterns that are formed having peaks and troughs, by exerting a pressure by the structuring surface (4) on the treated surface (5) of said thin film (6) of polymer electret for a duration T₁,
characterised in that
in a third step, once said nanometric patterns have formed in the thin film (6) of polymer electret, an electrical voltage is applied between said structuring surface (4) of the mould and said rear face (7) of said thin film (6) of polymer electret for a duration T₂ which is suitable for inducing a differential distribution of electrostatic charges between the peaks and troughs of the patterns formed, and
in a fourth step, said application of electrical voltage is stopped and the mould (2) is withdrawn from the surface of said thin film (6) of polymer electret.

2. Method according to claim 1, characterised in that said thin film (6) of polymer electret is deposited on a substrate (8).

3. Method according to claim 2, characterised in that said substrate (8) is made from a conductive or semi-conductive material.

4. Method according to claim 1, characterised in that said thin film (6) of polymer electret is made from a material selected from thermoplastic polymer materials and thermoset polymer materials.

5. Method according to claim 1, characterised in that:
said thin film (6) of polymer electret is made from a thermoplastic polymer material,
in the second step, after the film (6) has been brought to a temperature above the glass transition temperature of said thermoplastic polymer material, said pressure is exerted by the structuring surface (4) on the treated surface (5) of said thin film (6) of polymer electret.

6. Method according to claim 1, characterised in that the pressure exerted in the second step by said structuring surface (4) of the mould on the treated surface (5) of said thin film (6) of polymer electret is between 5 N and 5 000 N, particularly between 500 N and 2 000 N.

7. Method according to claim 1, characterised in that the thickness of said thin film (6) of polymer electret is less than 5 mm, particularly less than 1 mm, in particular less than 500 nm and more particularly less than 150 nm.

8. Method according to claim 1, characterised in that the mould (2) is made from a material selected from conductive materials and semi-conductive materials.

9. Method according to claim 1, characterised in that the mould (2) is made from a material selected from silicon, n-doped silicon, for example phosphorus-doped silicon, p-doped silicon, for example boron-doped silicon, and mixtures thereof.

10. Method according to claim 1, characterised in that the structuring patterns of the mould have a height of between 10 nm and 990 nm, particularly 50 nm and 300 nm, and at least one lateral dimension of between 5 nm and 500 μm, particularly 10 nm and 50 μm, and in particular 3 μm and 10 μm.

11. Method according to claim 1, characterised in that in the third step an electrical voltage not equal to zero is applied between the structuring surface (4) of the mould and the rear face (7) of the thin film (6) of polymer electret, of between −200 V and +200 V, particularly between −100 V and +100 V, in particular between −50 V and +50 V, and more particularly in the order of 25 V in absolute terms.

12. Method according to claim 1, characterised in that, in the third step, said electrical voltage is applied for a predetermined duration T₂ of between 1 second and 1 hour.

13. Method according to claim 1, characterised in that said thin film (6) of polymer electret obtained following the fourth step is brought into contact with micro-objects and/or nano-objects.

14. Method according to claim 13, characterised in that said micro-objects and/or nano-objects are electrically charged or electrically polarisable.

15. Method according to claim 1, characterised in that said thin film (6) of polymer electret obtained following the fourth step is immersed in a colloidal solution of nanoparticles.

16. Thin film made of polymer electret material obtained by the method according to claim 1, characterised in that it includes non-traversing nanometric patterns having peaks and troughs and having a differential distribution of electrostatic charges between the peaks and troughs of the patterns.

17. Thin film according to claim 16, characterised in that micro-objects and/or nano-objects, in particular nanoparticles, are disposed substantially, and in particular selectively only, in the troughs of said nanometric patterns formed.
